(19) United States
(12) Patent Application Publication
(10) Pub. No.: US 2023/0314956 A1
(43) Pub. Date: Oct. 5, 2023

(54) SUBSTRATE PROCESSING METHOD

(71) Applicant: SAMSUNG ELECTRONICS CO., LTD., Suwon-si (KR)

(72) Inventors: Sungkun KANG, Suwon-si (KR); Chawon KOH, Suwon-si (KR); Tsunehiro NISHI, Suwon-si (KR)

(21) Appl. No.: 18/125,923

(22) Filed: Mar. 24, 2023

(30) Foreign Application Priority Data
Apr. 1, 2022 (KR) 10-2022-0041335
Mar. 9, 2023 (KR) 10-2023-0031359

(51) Int. Cl. G03F 7/00; G03F 7/004; G03F 7/16; G03F 1/38; H01J 37/32

(52) U.S. Cl. CPC G03F 7/70033; G03F 7/0042; G03F 7/0025; G03F 7/0046; G03F 7/168; G03F 1/38; H01J 37/32458

(57) ABSTRACT

A substrate processing method includes forming a layer of an inorganic photoresist composition on a substrate, irradiating the layer of the inorganic photoresist composition with extreme ultraviolet (EUV) light using an exposure mask, baking the layer of the inorganic photoresist composition, which is irradiated with EUV light, developing the layer of the inorganic photoresist composition using a developer to form a first inorganic photoresist pattern, performing plasma treatment on the first inorganic photoresist pattern to form a second inorganic photoresist pattern, and processing the substrate using the second inorganic photoresist pattern as a process mask, wherein the plasma treatment uses plasma of a process gas capable of generating hydrogen ions and fluorine ions.

### CROSS-REFERENCE TO RELATED APPLICATION

This application is based on and claims priority under 35 U.S.C. § 119 to Korean Patent Application No. 10-2022-0041335, filed on Apr. 1, 2022, in the Korean Intellectual Property Office, the disclosure of which is incorporated by reference herein in its entirety.

### BACKGROUND

### 1. Field

Embodiments relate to a substrate processing method.

### 2. Description of the Related Art

To apply extreme ultraviolet lithography techniques, it is important to improve characteristics such as line edge roughness to prevent pattern defects. In particular, when inorganic photoresists are used, there is a demand for methods providing improved characteristics, such as line edge roughness, simultaneously with improving selectivity through an improvement of etch resistance.

### SUMMARY

An embodiment is directed to a substrate processing method including forming a layer of an inorganic photoresist composition on a substrate, irradiating the layer of the inorganic photoresist composition with extreme ultraviolet (EUV) light using an exposure mask, baking the layer of the inorganic photoresist composition, which is irradiated with EUV light, developing the layer of the inorganic photoresist composition using a developer to form a first inorganic photoresist pattern, performing plasma treatment on the first inorganic photoresist pattern to form a second inorganic photoresist pattern, and processing the substrate using the second inorganic photoresist pattern as a process mask, wherein the plasma treatment uses plasma of a process gas capable of generating hydrogen ions and fluorine ions.

An embodiment is directed to a substrate processing method including forming, on a substrate, a layer of an inorganic photoresist composition including a crosslinkable molecule represented by Formula 1, forming an exposed region and a non-exposed region by exposing the layer of the inorganic photoresist composition using an exposure mask, baking the layer of the inorganic photoresist composition, which is exposed, developing the layer of the inorganic photoresist composition using a developer to form a first inorganic photoresist pattern, performing plasma treatment on the first inorganic photoresist pattern to form a second inorganic photoresist pattern, and processing the substrate using the second inorganic photoresist pattern as a process mask,

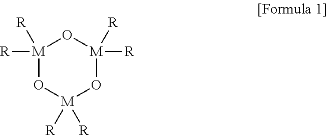

wherein, in Formula 1, M includes at least one of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn), R includes an alkyl group.

An embodiment is directed to a substrate processing method including forming, on a substrate, a layer of an inorganic photoresist composition including a tin (Sn)-oxygen (O) bond, forming an exposed region and a non-exposed region by exposing the layer of the inorganic photoresist composition to extreme ultraviolet (EUV) light using an exposure mask, developing the layer of the inorganic photoresist composition using a developer to form a first inorganic photoresist pattern, performing plasma treatment on the first inorganic photoresist pattern to form a second inorganic photoresist pattern, and processing the substrate using the second inorganic photoresist pattern as a process mask. Here, the plasma treatment is performed using a process gas including one of the following (i) to (v): (i) a C1 to C3 fluorine-containing hydrocarbon including at least one hydrogen atom, (ii) a mixed gas of hydrogen (H₂) and a perfluorinated compound, (iii) a mixed gas of a perfluorinated compound and a C1 to C3 fluorine-containing hydrocarbon including at least one hydrogen atom, (iv) a mixed gas of hydrogen (H₂) and a C1 to C3 fluorine-containing hydrocarbon, and (v) a mixed gas of a C1 to C3 fluorine-containing hydrocarbon, hydrogen (H₂), and a perfluorinated compound.

### BRIEF DESCRIPTION OF THE DRAWINGS

Features will become apparent to those of skill in the art by describing in detail example embodiments with reference to the attached drawings in which:

FIG. 1 is a flowchart illustrating a substrate processing method according to an example embodiment;

FIGS. 2A to 2F are cross-sectional views illustrating a sequence of processes of a substrate processing method, according to an example embodiment;

FIG. 3A illustrates cross-sectional and planar images of a photoresist pattern of Comparison Example 1, and FIG. 3B illustrates cross-sectional and planar images of a photoresist pattern of Example 1; and

FIG. 4 is a graph depicting a degree of improvement in LER according to a process time of plasma treatment.

### DETAILED DESCRIPTION

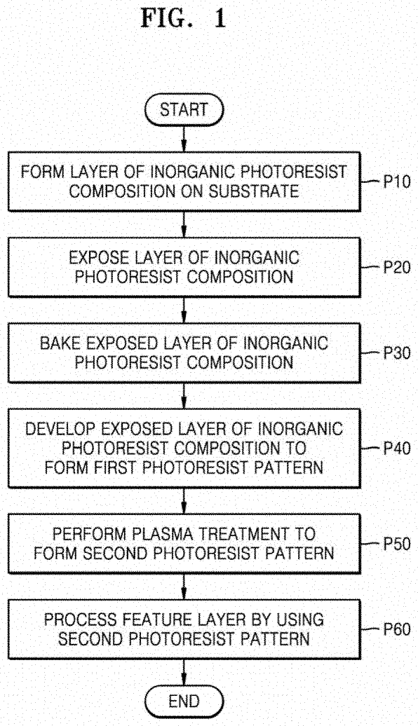

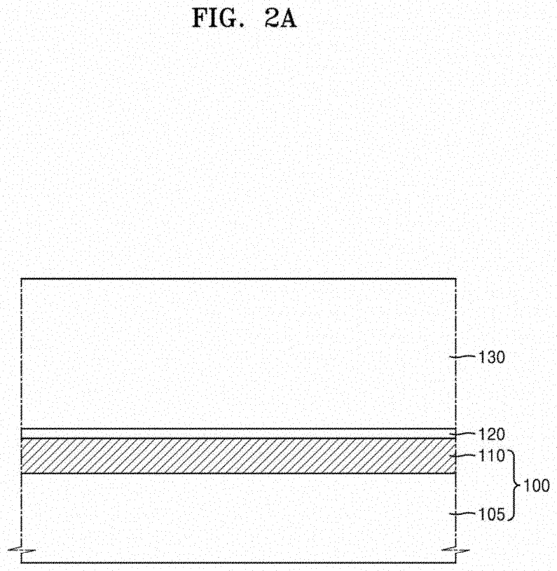

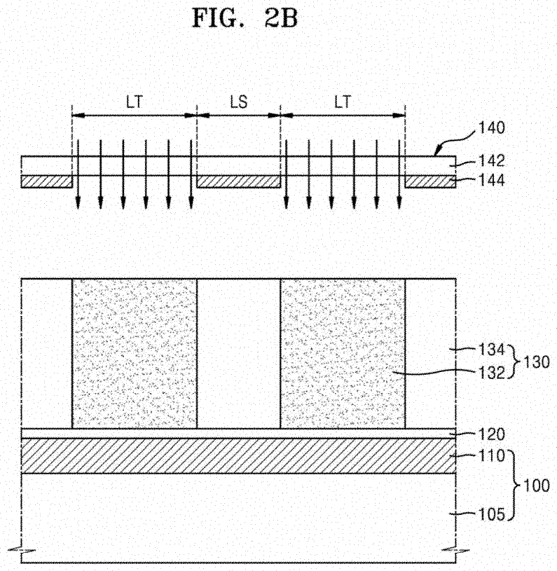

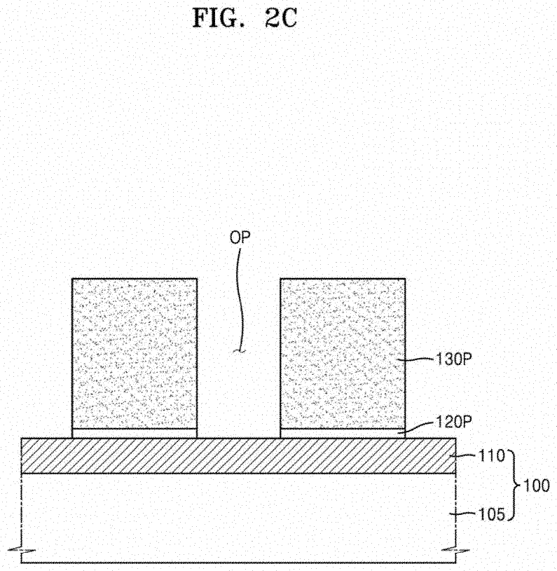

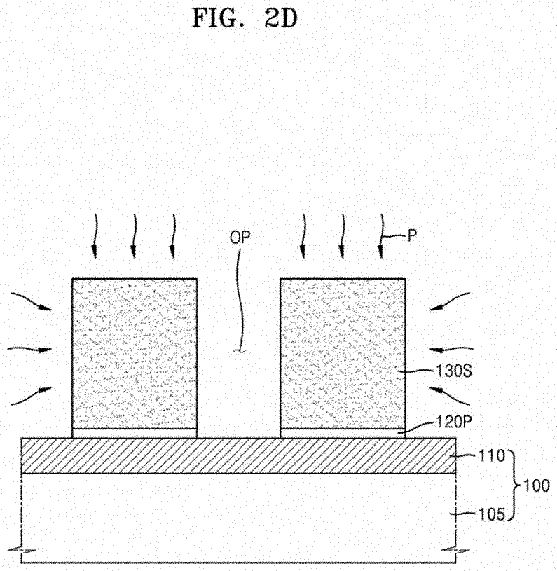

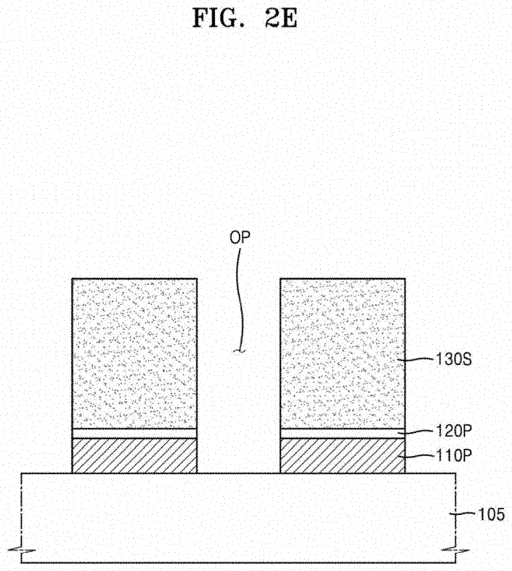

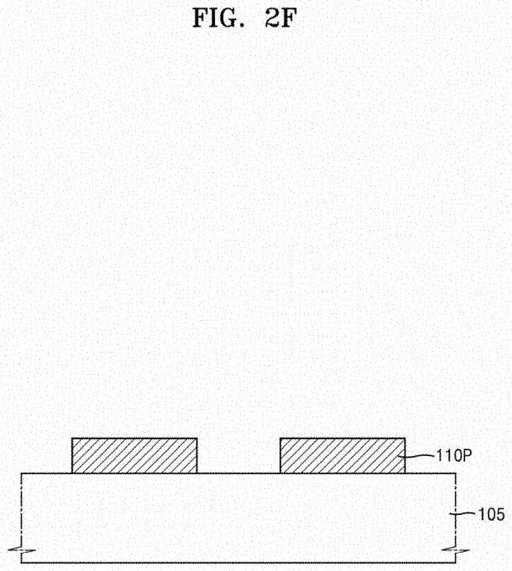

FIG. 1 is a flowchart illustrating a substrate processing method according to an example embodiment. FIGS. 2A to 2F are cross-sectional views illustrating a sequence of processes of a substrate processing method, according to an example embodiment.

Referring to FIGS. 1 and 2A, in process P10, a layer 130 of an inorganic photoresist composition may be formed on a substrate 100 using the inorganic photoresist composition. The substrate 100 may include a lower material film 105 and a feature layer 110 formed on the lower material film 105.

The layer 130 of the inorganic photoresist composition may include a crosslinkable molecule represented by Formula 1:

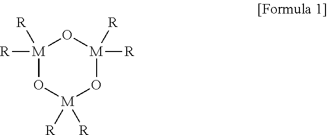

In Formula 1,
M includes at least one of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R includes an alkyl group.

According to an embodiment, each of the six R bonded to M may include the same alkyl group. According to another embodiment, each of the six R bonded to M may include the different alkyl group. In accordance with another embodiment, at least two R among the six R respectively bonded to M may include the same alkyl group, and other R may include an alkyl group different from the two R.

The crosslinkable molecule represented by Formula 1 may form a covalent bond with another crosslinkable molecule by exposure to irradiation of a specific-wavelength light or an electron-beam (e-beam) and thus form a macromolecule.

The crosslinkable molecule represented by Formula 1 may be a crosslinkable molecule represented by Formula 1-1:

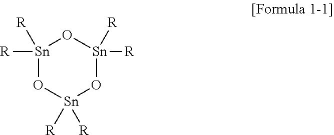

In Formula 1-1, X and Rf are the same as for Formula 1.

The crosslinkable molecule represented by Formula 1 may be cross-linked in the form of Sn—O—Sn or Sn—Sn bond by exposure, and relatively strong cross-linking bond may be obtained to prevent pattern collapse. In addition the crosslinkable molecule represented by Formula 1 may provide excellent etch resistance due to a metal (e.g., M) contained therein.

The layer 130 of the inorganic photoresist composition may include a crosslinkable molecule represented by Formula 2:

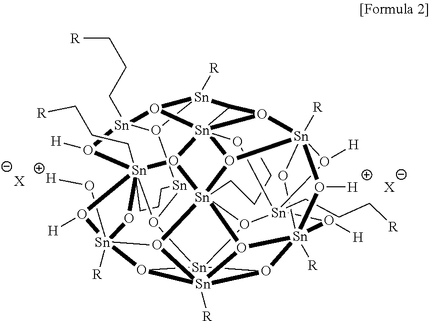

R includes an alkyl group.

According to an embodiment, each of R bonded to M may include the same alkyl group. According to another embodiment, each of R bonded to M may include different alkyl group. In accordance with another embodiment, at least two R among the R respectively bonded to M may include the same alkyl group, and other R may include an alkyl group different from the two R.

The layer 130 of the inorganic photoresist composition may include a crosslinkable molecule represented by Formula 3:

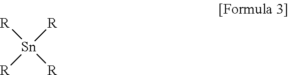

R includes an alkyl group.

According to an embodiment, each of the four R bonded to M may include the same alkyl group. According to another embodiment, each of the four R bonded to M may include the different alkyl group. In accordance with another embodiment, at least two R among the six R respectively bonded to M may include the same alkyl group, and other R may include an alkyl group different from the two R.

The layer 130 of the inorganic photoresist composition may include a crosslinkable molecule represented by Formula 4:

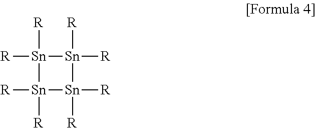

R includes an alkyl group.

According to an embodiment, each of the eight R bonded to M may include the same alkyl group. According to another embodiment, each of the eight R bonded to M may include the different alkyl group. In accordance with another embodiment, at least two R among the eight R respectively bonded to M may include the same alkyl group, and other R may include an alkyl group different from the two R.

The lower material film 105 may include a semiconductor substrate.

The semiconductor substrate may include a semiconductor, such as Si or Ge, or a compound semiconductor, such as SiGe, SiC, GaAs, InAs, or InP. The semiconductor substrate may include at least one of a Group III-V material or a Group IV material. The Group III-V material may include a 2-membered, 3-membered, or 4-membered compound including at least one Group III atom and at least one Group V atom. The Group III-V material may include a compound including at least one of In, Ga, and Al atoms as a Group III atom, and at least one of As, P, and Sb atoms as a Group V atom. For example, the Group III-V material may be selected from InP, In_{z}Ga_{1-z}As (0≤z≤1), and Al_{z}Ga_{1-z}As (0≤z≤1). The 2-membered compound may include, e.g., one of InP, GaAs, InAs, InSb, and GaSb. The 3-membered compound may include one of InGaP, InGaAs, AlInAs, InGaSb, GaAsSb, and GaAsP. The Group IV material may include Si or Ge. In another example, the semiconductor substrate may have a silicon-on-insulator (SOI) structure. The semiconductor substrate may include a conductive region, e.g., an impurity-doped well or an impurity-doped structure.

The feature layer 110 may include an insulating film, a conductive film, or a semiconductor film. For example, the feature layer 110 may include a metal, an alloy, a metal carbide, a metal nitride, a metal oxynitride, a metal oxycarbide, a semiconductor, polysilicon, an oxide, a nitride, an oxynitride, or a combination thereof.

Referring to FIG. 2A, before the layer 130 of an inorganic photoresist composition is formed on the feature layer 110, a functional film 120 may be formed on the feature layer 110. In this case, the layer 130 of an inorganic photoresist composition may be formed on the functional film 120.

The functional film 120 may prevent the layer 130 of an inorganic photoresist composition from being adversely affected by the feature layer 110 under the functional film 120. The functional film 120 may include an organic or inorganic anti-reflective coating (ARC) material for KrF excimer lasers, ArF excimer lasers, EUV lasers, or any other light sources. The functional film 120 may include a bottom anti-reflective coating (BARC) film or a developable bottom anti-reflective coating (DBARC) film. The functional film 120 may include an organic component having a light absorption structure. The light absorption structure may include, e.g., a hydrocarbon compound having a structure in which one or more benzene rings are fused. The functional film 120 may have a thickness of about 1 nm to about 100 nm. The functional film 120 may be omitted.

To form the layer 130 of the inorganic photoresist composition, the inorganic photoresist composition may be coated on the functional film 120 and then heat-treated.

The coating may be performed by a method, such as spin coating, spray coating, dip coating, or the like.

The process of heat-treating the inorganic photoresist composition may be performed at a temperature of about 80° C. to about 300° C. for about 10 seconds to about 100 seconds.

The thickness of the layer 130 of the inorganic photoresist composition may be tens to hundreds of times the thickness of the functional film 120. The layer 130 of the inorganic photoresist composition may have a thickness of about 10 nm to about 1 μm.

Referring to FIGS. 1 and 2B, in process P20, a first region 132, which is a portion of the layer 130 of the inorganic photoresist composition, is exposed, thereby forming a macromolecule, which is difficult to remove by a developer, by crosslinking of the Sn—O—Sn or Sn—Sn of the crosslinkable molecule in the first region 132.

Crosslinkable molecules in the exposed first region 132 are linked to each other and thus form a macromolecule, and crosslinkable molecules in a non-exposed second region 134 are not linked to each other. Accordingly, there is a difference in solubility between the crosslinked macromolecule and the non-crosslinked crosslinkable molecules.

The layer 130 of the inorganic photoresist composition may include a photoacid generator (PAG).

To expose the first region 132 of the layer 130 of the inorganic photoresist composition, an exposure mask 140, which has a plurality of light shielding areas LS and a plurality of light transmitting areas LT, may be aligned at a certain position over the layer 130 of the inorganic photoresist composition, and the first region 132 of the layer 130 of the inorganic photoresist composition may be exposed through the plurality of light transmitting areas LT of the exposure mask 140. To expose the first region 132 of the layer 130 of the inorganic photoresist composition, a KrF excimer laser (248 nm), an ArF excimer laser (193 nm), an F2 excimer laser (157 nm), or an EUV laser (13.5 nm) may be used. A reflective photomask may be used instead of a transmissive photomask, according to the type of light source.

Although descriptions will be made hereinafter by mainly taking an example using a transmissive photomask, it will be understood by those of ordinary skill in the art that the exposure may also be performed by an equivalent configuration using a reflective photomask.

The exposure mask 140 may include a transparent substrate 142, and a plurality of light shielding patterns 144 formed in the plurality of light shielding areas LS on the transparent substrate 142. The transparent substrate 142 may include quartz. The plurality of light shielding patterns 144 may include chromium (Cr). The plurality of light transmitting areas LT may be defined by the plurality of light shielding patterns 144.

To expose the first region 132 of the layer 130 of the inorganic photoresist composition, a reflective exposure mask (not shown) for EUV exposure may be used instead of the exposure mask 140.

On the other hand, in the non-exposed second region 134, because the crosslinkable molecules remain substantially as they are instead of forming a macromolecule, the second region 134 has a difference from the first region 132 in terms of solubility in a developer.

After the first region 132 of the layer 130 of the inorganic photoresist composition is exposed according to process P20, the layer 130 of the inorganic photoresist composition may be subjected to baking (P30).

The baking may be performed at a temperature of about 50° C. to about 400° C. for about 10 seconds to about 100 seconds.

During the baking of the layer 130 of the inorganic photoresist composition, a degree of crosslinking between the crosslinkable molecules in the first region 132 may be further increased. Accordingly, a difference in solubility in a developer between the exposed first region 132 and the non-exposed second region 134 of the layer 130 of the inorganic photoresist composition may be further increased, and pattern collapse may be prevented.

Referring to FIGS. 1 and 2C, in process P40, to form a first inorganic photoresist pattern 130P, the layer 130 of the inorganic photoresist composition may be developed using a developer. For example, the second region 134 of the layer 130 of the inorganic photoresist composition may be removed using the developer. As a result, the first inorganic photoresist pattern 130P including the exposed first region 132 of the layer 130 of the inorganic photoresist composition may be formed.

In embodiments, when the layer 130 of the inorganic photoresist composition is a negative photoresist, the developer may include a propylene glycol monomer ether acetate (PGMEA) developer. In this case, the second region 134 of the layer 130 of the inorganic photoresist composition not irradiated by light is removed, and only the first region 132 of the layer 130 of the inorganic photoresist remains to form the first inorganic photoresist pattern 130P.

However, although not shown in the drawings, if the layer 130 of the inorganic photoresist composition is a positive photoresist according to the embodiment, the developer may include a water-soluble developer, such as Tetramethylammonium hydroxide (TMAH). In this case, the first region 132 of the layer 130 of the inorganic photoresist composition irradiated with light is removed, and only the second region 134 of the layer 130 of the inorganic photoresist composition remains, forming another type of inorganic photoresist pattern.

The first inorganic photoresist pattern 130P may include a plurality of openings OP. After the first inorganic photoresist pattern 130P is formed, a functional pattern 120P may be formed by removing portions of the functional film 120, which are exposed by the plurality of openings OP.

The first inorganic photoresist pattern 130P may include any pattern intended to be transferred to the feature layer 110, e.g., a line-and-space pattern, a hole pattern, or the like.

The development of the layer 130 of the inorganic photoresist composition may be performed by a negative-tone development (NTD) process. Here, n-butyl acetate or 2-heptanone may be used as the developer.

As described with reference to FIG. 2B, as the difference in solubility in the developer between the exposed first region 132 and the non-exposed second region 134 in the layer 130 of the inorganic photoresist composition increases, while the second region 134 is removed by developing the layer 130 of the inorganic photoresist composition in the process of FIG. 2C, the first region 132 may remain almost as it is without being removed. Therefore, after the layer 130 of the inorganic photoresist composition is developed, residual defects such as footing are not generated, and a vertical sidewall profile may be obtained in the first inorganic photoresist pattern 130P.

Referring to FIGS. 1 and 2D, in process P50, a second inorganic photoresist pattern 130S is obtained by performing plasma treatment on the first inorganic photoresist pattern 130P.

The plasma treatment may be performed by generating plasma of a specific process gas while supplying the process gas, followed by applying the plasma to the first inorganic photoresist pattern 130P.

The process gas may generate hydrogen ions and fluorine ions when converted into a plasma state. Thus, the process gas may include a single gas or a gas mixture, which includes a hydrogen supply source and a fluorine supply source. For example, the process gas may include one of the following (i) to (v).
(i) a C1 to C3 fluorine-containing hydrocarbon including at least one hydrogen atom,
(ii) a mixed gas of hydrogen (H₂) and a perfluorinated compound,
(iii) a mixed gas of a perfluorinated compound and a C1 to C3 fluorine-containing hydrocarbon including at least one hydrogen atom,
(iv) a mixed gas of hydrogen (H₂) and a C1 to C3 fluorine-containing hydrocarbon, and
(v) a mixed gas of a C1 to C3 fluorine-containing hydrocarbon, hydrogen (H₂), and a perfluorinated compound.

The perfluorinated compound of (ii), (iii), and (v) may be a compound having a formula of QₓF_{y}. Here, Q may be one of carbon (C), sulfur (S), and nitrogen (N). In addition, x is an integer of 1 to 3, and y is the number of fluorine (F) atoms capable of being bonded to x Q atoms. For example, QₓF_{y} may include CF₄, SF₆, NF₃, C₂F₄, C₂F₆, C₃F₆, C₃F₈, C₄F₈, C₄F₁₀, or a combination thereof.

The C1 to C3 fluorine-containing hydrocarbon including at least one hydrogen atom may include CHF₃, CH₂F₂, C₂HF₃, C₂H₂F₂, C₂HF₅, C₂H₂F₄, C₂H₃F₃, C₂H₄F₂, C₃HF₅, C₃H₂F₄, C₃H₃F₃, C₃H₄F₂, C₃HF₇, C₃H₂F₆, C₃H₃F₅, C₃H₄F₄, C₃H₅F₃, C₃H₆F₂, or a combination thereof.

The process gas may further include an inert gas, such as helium (He), neon (Ne), argon (Ar), or the like.

The flow rate of the process gas for the plasma treatment may be, e.g., about 20 sccm to about 250 sccm. In some embodiments, the flow rate of the process gas may be adjusted to a range of about 20 sccm to about 250 sccm, about 30 sccm to about 230 sccm, about 40 sccm to about 200 sccm, about 50 sccm to about 180 sccm, about 60 sccm to about 160 sccm, about 70 sccm to about 140 sccm, or about 80 sccm to about 120 sccm, or a range between any two of these numerical values.

The pressure of a chamber for the plasma treatment may be, e.g., about 0.5 mTorr to about 100 mTorr. The pressure of the chamber may be adjusted to a range of about 0.5 mTorr to about 100 mTorr, about 1 mTorr to about 80 mTorr, about 1.5 mTorr to about 50 mTorr, about 2 mTorr to about 30 mTorr, about 2.5 mTorr to about 20 mTorr, about 3 mTorr to about 15 mTorr, about 3.5 mTorr to about 10 mTorr, or about 4 mTorr to about 8 mTorr, or a range between any two of these numerical values.

The plasma treatment may be performed for about 3 seconds to about 30 seconds under the conditions set forth above. The time period of the plasma treatment may be adjusted to a range of about 3 seconds to about 30 seconds, about 4 seconds to about 25 seconds, about 5 seconds to about 20 seconds, about 6 seconds to about 18 seconds, about 7 seconds to about 15 seconds, or about 8 seconds to about 12 seconds, or a range between any two of these numerical values.

When the plasma treatment is performed using the process gas, the first inorganic photoresist pattern 130P may be converted into the second inorganic photoresist pattern 130S.

The second inorganic photoresist pattern 130S may include a metal-fluorine bond at a surface thereof. Thus, when the metal M in Formula 1 is tin (Sn), the second inorganic photoresist pattern 130S may include an Sn—F bond at the surface thereof.

Without being bound by theory, it is believed that, when the plasma treatment is performed using the process gas including a hydrogen supply source and a fluorine supply source as described above, the metal M or a metal oxide (MOₓ) at the surface of the first inorganic photoresist pattern 130P reacts with hydrogen and thus is reduced, and carbon inside the first inorganic photoresist pattern 130P also reacts with hydrogen. Simultaneously, the metal M at the surface of the first inorganic photoresist pattern 130P forms an M-F bond (an Sn—F bond when the metal M in Formula 1 is tin) by reacting with fluorine of the process gas, and it is believed that, during this process, atoms at the surface of the first inorganic photoresist pattern 130P are rearranged, thereby obtaining the second inorganic photoresist pattern 130S that is more smooth. Therefore, when the first inorganic photoresist pattern 130P is a line-and-space pattern, the second inorganic photoresist pattern 130S may have significantly improved LER and LWR as compared with the first inorganic photoresist pattern 130P. In addition, because the M-F bond at the surface of the second inorganic photoresist pattern 130S may have high mutual bond strength and low volatility, the second inorganic photoresist pattern 130S may have high etch resistance.

A heat treatment for hard baking may be further performed on the second inorganic photoresist pattern 130S. The heat treatment may be performed, e.g., at a temperature of about 120° C. to about 150° C. for about 10 seconds to about 100 seconds.

Referring to FIGS. 1 and 2E, in process P60, in a resulting product of FIG. 2D, the feature layer 110 may be processed using the second inorganic photoresist pattern 130S.

To process the feature layer 110, various processes, such as a process of etching the feature layer 110 exposed by the openings OP of the second inorganic photoresist pattern 130S, a process of implanting impurity ions into the feature layer 110, a process of forming an additional film on the feature layer 110 through the openings OP, and a process of modifying portions of the feature layer 110 through the openings OP, may be performed. FIG. 2E illustrates, as an example of a process of processing the feature layer 110, an example of forming a feature pattern 110P by etching the feature layer 110 exposed by the openings OP.

The process of forming the feature layer 110 may be omitted from the process described with reference to FIG. 2A, and in this case, instead of process P60 of FIG. 1 and the process described with reference to FIG. 2E, the lower material film 105 may be processed using the second inorganic photoresist pattern 130S. For example, various processes, such as a process of etching a portion of the lower material film 105 using the second inorganic photoresist pattern 130S, a process of implanting impurity ions into some regions of the lower material film 105, a process of forming an additional film on the lower material film 105 through the openings OP, and a process of modifying portions of the lower material film 105 through the openings OP, may be performed.

The feature layer 110 may include a hardmask material film. For example, the feature layer 110 may include an amorphous carbon layer (ACL), a spin-on hardmask (SOH), silicon oxide, silicon nitride, silicon oxynitride, a metal such as Ti, Al, or W or an alloy thereof, or the like. When the feature layer 110 includes a hardmask material film, a new hardmask may be obtained by etching the feature layer 110 using the second inorganic photoresist pattern 130S as an etch mask.

Referring to FIG. 2F, in a resulting product of FIG. 2E, the second inorganic photoresist pattern 130S and the functional pattern 120P, which remain on the feature pattern 110P, may be removed. To remove the second inorganic photoresist pattern 130S and the functional pattern 120P, ashing and strip processes may be used.

According to the substrate processing method described with reference to FIGS. 1 and 2A to 2F, after a photoresist pattern is formed by exposure and development, plasma treatment may be performed on the photoresist pattern using a process gas, which may improve the LER, LWR, and etch resistance of the photoresist pattern.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

A photoresist solution, in which crosslinkable molecules including tin were dissolved to 5 wt/vol % in PF-7600 (3M Co., Ltd.), was spin-coated on an Si substrate at 3000 rpm for 60 seconds and then heated at 110° C. for 1 minute, thereby forming a thin film having a thickness of about 100 nm. Next, the thin film was exposed to EUV light having a wavelength of 13.5 nm through an exposure mask, followed by performing a development process for 20 seconds using HFE-7100, which is a highly fluorinated solvent, thereby forming a photoresist pattern having line widths of 70 nm and 100 nm.

Next, the photoresist pattern was treated in a plasma chamber at a chamber pressure of 5 mTorr and an RF power of 1500 W for 10 seconds using a mixed gas of H₂ and CHF₃ (volume ratio of 1:3) as a process gas, while the mixed gas was supplied at a flow rate of 100 sccm.

### Comparison Example 1

A photoresist pattern was formed in the same manner as in Example 1, except that plasma treatment was not performed on the photoresist pattern.

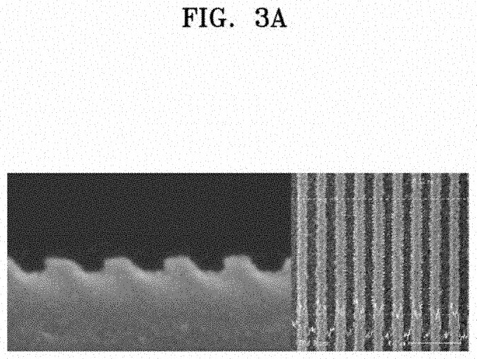

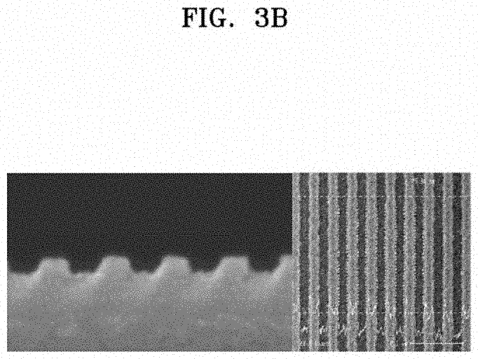

FIG. 3A illustrates cross-sectional and planar images of the photoresist pattern of Comparison Example 1, and FIG. 3B illustrates cross-sectional and planar images of the photoresist pattern of Example 1.

Comparing FIG. 3A with FIG. 3B, it can be confirmed that the cross-section of the photoresist pattern of Example 1 had a more rounded corner than the cross-section of the photoresist pattern of Comparison Example 1.

In addition, comparing the planar image of the photoresist pattern of Example 1 with the planar image of the photoresist pattern of Comparison Example 1, it can be confirmed that the LER of the photoresist pattern of Example 1 was improved as compared with the LER of the photoresist pattern of Comparison Example 1.

To check a degree of improvement in LER, LER was measured on three points of the Si substrate, followed by calculating the degree of improvement as an improvement rate (percentage). Results are shown in Table 1:

TABLE 1

| | Improvement(%) |
|---|---|
| Point 1 | 13 |
| Point 2 | 15 |
| Point 3 | 14 |

As shown in Table 1, it can be confirmed that there was an overall LER improvement through the plasma treatment regardless of the points of the Si substrate.

### Example 2

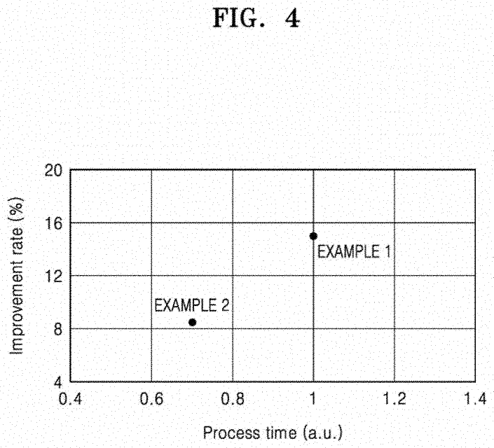

A photoresist pattern was formed in the same manner as in Example 1 except that the process time of plasma treatment was 7 seconds. An improvement rate (%) was calculated as compared with Comparison Example 1. Results are shown in FIG. 4.

Referring to FIG. 4, while it was confirmed that the improvement rate of LER in Example 2 was about 9%, it was confirmed that the improvement rate of LER in Example 1 was about 15%. That is, it was confirmed that the LER was further improved along with the increasing process time of plasma treatment.

As described above, example embodiments relate to a substrate processing method in which line edge roughness, line width roughness, and etch resistance may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate processing method, comprising:
forming a layer of an inorganic photoresist composition on a substrate;
irradiating the layer of the inorganic photoresist composition with extreme ultraviolet (EUV) light using an exposure mask;
baking the layer of the inorganic photoresist composition, which has been irradiated with EUV light;
developing the layer of the inorganic photoresist composition using a developer to form a first inorganic photoresist pattern;
performing plasma treatment on the first inorganic photoresist pattern to form a second inorganic photoresist pattern; and
processing the substrate using the second inorganic photoresist pattern as a process mask,
wherein the plasma treatment uses plasma of a process gas capable of generating hydrogen ions and fluorine ions.

2. The method of claim 1, wherein the process gas includes one of the following (i) to (v):
(i) a C1 to C3 fluorine-containing hydrocarbon including at least one hydrogen atom;
(ii) a mixed gas of hydrogen (H₂) and a perfluorinated compound;
(iii) a mixed gas of a perfluorinated compound and a C1 to C3 fluorine-containing hydrocarbon including at least one hydrogen atom;
(iv) a mixed gas of hydrogen (H₂) and a C1 to C3 fluorine-containing hydrocarbon; and
(v) a mixed gas of a C1 to C3 fluorine-containing hydrocarbon, hydrogen (H₂), and a perfluorinated compound.

3. The method of claim 2, wherein, in (ii), (iii), and (v), the perfluorinated compound is represented by a formula of QₓF_{y} in which:
Q is one of carbon (C), sulfur (S), and nitrogen (N),
x is an integer of 1 to 3, and
y is a number of fluorine (F) atoms capable of being bonded to x Q atoms.

4. The method of claim 2, wherein, in (ii), (iii), and (v), the perfluorinated compound is CF₄, SF₆, NF₃, C₂F₄, C₂F₆, C₃F₆, C₃F₈, C₄F₈, C₄F₁₀, or a combination thereof.

5. The method of claim 2, wherein the C1 to C3 fluorine-containing hydrocarbon including at least one hydrogen atom is CHF₃, CH₂F₂, C₂HF₃, C₂H₂F₂, C₂HF₅, C₂H₂F₄, C₂H₃F₃, C₂H₄F₂, C₃HF₅, C₃H₂F₄, C₃H₃F₃, C₃H₄F₂, C₃HF₇, C₃H₂F₆, C₃H₃F₅, C₃H₄F₄, C₃H₅F₃, C₃H₆F₂, or a combination thereof.

6. The method of claim 2, further comprising, after the performing of the plasma treatment and before the processing of the substrate, baking the second inorganic photoresist pattern.

7. The method of claim 2, wherein the plasma treatment is performed for about 3 seconds to about 30 seconds.

8. The method of claim 2, wherein the plasma treatment is performed at a chamber pressure of about 0.5 mTorr to about 100 mTorr.

9. The method of claim 2, wherein a flow rate of the process gas is about 20 sccm to about 250 sccm.

10. The method of claim 1, wherein the inorganic photoresist composition includes a crosslinkable molecule represented by Formula 1: 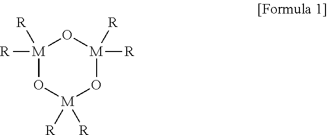
wherein, in Formula 1,
M includes at least one of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R includes an alkyl group.

11. The method of claim 1, wherein the inorganic photoresist composition includes a crosslinkable molecule represented by Formula 2: 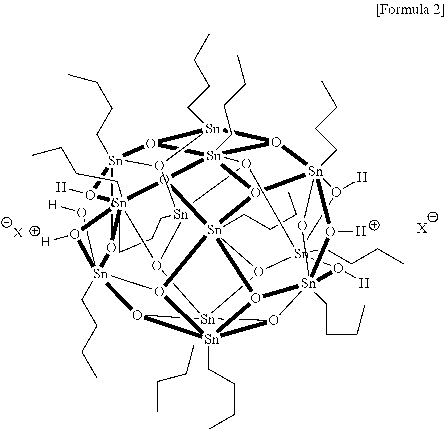
Wherein, in Formula 2,
R includes an alkyl group, and
X includes a halogen element.

12. A substrate processing method, comprising:
forming, on a substrate, a layer of an inorganic photoresist composition including a crosslinkable molecule represented by Formula 1;
forming an exposed region and a non-exposed region by exposing the layer of the inorganic photoresist composition using an exposure mask;
baking the layer of the inorganic photoresist composition, which has been exposed;
developing the layer of the inorganic photoresist composition using a developer to form a first inorganic photoresist pattern;
performing plasma treatment on the first inorganic photoresist pattern to form a second inorganic photoresist pattern; and
processing the substrate using the second inorganic photoresist pattern as a process mask, 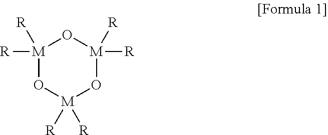
wherein, in Formula 1,
M includes at least one of tin (Sn), zinc (Zn), lithium (Li), sodium (Na), potassium (K), beryllium (Be), magnesium (Mg), calcium (Ca), barium (Ba), aluminum (Al), silicon (Si), cadmium (Cd), mercury (Hg), chromium (Cr), iron (Fe), cobalt (Co), nickel (Ni), copper (Cu), germanium (Ge), palladium (Pd), platinum (Pt), lead (Pb), strontium (Sr), and manganese (Mn),
R includes an alkyl group.

13. The method of claim 12, wherein M in Formula 1 is tin (Sn).

14. The method of claim 12, wherein:
the substrate includes a lower material film and a hardmask material film on the lower material film, and
the processing of the substrate includes:
patterning the hardmask material film using the second inorganic photoresist pattern as a patterning mask to form a hardmask; and
patterning the lower material film using the hardmask as a patterning mask.

15. The method of claim 14, wherein the second inorganic photoresist pattern includes a line-and-space pattern.

16. The method of claim 12, wherein the plasma treatment is performed using a process gas that includes one of the following (i) to (v):
(i) a C1 to C3 fluorine-containing hydrocarbon including at least one hydrogen atom;
(ii) a mixed gas of hydrogen (H₂) and a perfluorinated compound;
(iii) a mixed gas of a perfluorinated compound and a C1 to C3 fluorine-containing hydrocarbon including at least one hydrogen atom;
(iv) a mixed gas of hydrogen (H₂) and a C1 to C3 fluorine-containing hydrocarbon; and
(v) a mixed gas of a C1 to C3 fluorine-containing hydrocarbon, hydrogen (H₂), and a perfluorinated compound.

17. The method of claim 16, wherein, in (ii), (iii), and (v) the perfluorinated compound is CF₄, SF₆, NF₃, C₂F₄, C₂F₆, C₃F₆, C₃F₈, C₄F₈, C₄F₁₀, or a combination thereof.

18. The method of claim 16, wherein the plasma treatment is performed at a chamber pressure of about 0.5 mTorr to about 100 mTorr for about 3 seconds to about 30 seconds while the process gas is supplied at a flow rate of about 20 sccm to about 250 sccm.

19. The method of claim 12, wherein the second inorganic photoresist pattern has an Sn—F bond at a surface thereof.

20. A substrate processing method, comprising:
forming, on a substrate, a layer of an inorganic photoresist composition including a tin (Sn)-oxygen (O) bond;
forming an exposed region and a non-exposed region by exposing the layer of the inorganic photoresist composition to extreme ultraviolet (EUV) light using an exposure mask;
developing the layer of the inorganic photoresist composition using a developer to form a first inorganic photoresist pattern;
performing plasma treatment on the first inorganic photoresist pattern to form a second inorganic photoresist pattern; and
processing the substrate using the second inorganic photoresist pattern as a process mask,
wherein the plasma treatment is performed using a process gas that includes one of the following (i) to (v):
(i) a C1 to C3 fluorine-containing hydrocarbon including at least one hydrogen atom;
(ii) a mixed gas of hydrogen (H₂) and a perfluorinated compound;
(iii) a mixed gas of a perfluorinated compound and a C1 to C3 fluorine-containing hydrocarbon including at least one hydrogen atom;
(iv) a mixed gas of hydrogen (H₂) and a C1 to C3 fluorine-containing hydrocarbon; and
(v) a mixed gas of a C1 to C3 fluorine-containing hydrocarbon, hydrogen (H₂), and a perfluorinated compound.
